(19) United States
(12) Patent Application Publication
(10) Pub. No.: US 2007/0014095 A1
(43) Pub. Date: Jan. 18, 2007

(54) High-performance separable electrical device/printed circuit board interconnection

(76) Inventor: Roger E. Weiss, Foxboro, MA (US)

Correspondence Address: MIRICK, O'CONNELL, DEMALLIE & LOUGEE, 100 FRONT STREET, WORCESTER, MA, 01608, US

(21) Appl. No.: 11/180,303

(22) Filed: Jul. 12, 2005

(51) Int. Cl. H05K 7/00

(52) U.S. Cl. 361/760; 361/769

(57) ABSTRACT

A high-performance separable electrical device/printed circuit board interconnection for an electrical device package having surface contacts on an active surface thereof, wherein the package is separably placed proximate to, and is electrically connected through its contacts to, an active surface of the printed circuit board, the package having one or more projections extending from the active surface farther than the electrical device package surface contacts. The interconnection is defined by a low-profile surface mount connector for accomplishing the electrical connection between the printed circuit board and the electrical device package, and a printed circuit board with an active surface having electrical connections thereon, wherein there are one or more recesses defined in the printed circuit board and/or in the surface mount connector, the recesses aligned with the projections extending from the active surface of the device package when the package is electrically connected to the printed circuit board, such that the projections fit into the recesses without touching the printed circuit board.

### FIELD OF THE INVENTION

This invention relates to a separable interconnection between an electrical device and a circuit board.

### BACKGROUND OF THE INVENTION

Separable interconnection between an electrical device and printed circuit board has historically been accomplished using a contact member such as a spring probe as shown in FIG. 1, comprising barrel 10, spring 11, and contact 12. Alternative arrangements include pin-in socket structures, or formed metal contacts. These contact members tend to be long, causing the device to sit well above the surface of the board. Also, as the electronic industry moves to higher speed, these conventional means of providing interconnection do not have the electrical characteristics needed to conduct the high-speed signals.

High-speed electrical interconnection requires the use of very low profile interconnection having short electrical path lengths, such as that provided by surface mount connectors. One example of a surface mount connector that provides the needed performance is shown in FIG. 2. This consists of a layer of conductive pads on the device package 20, and a matching pad layer on the board 22, separated by a layer of Anisotropic Conductive Elastomer (ACE) 24. Vertically-aligned pads 23 and 25 illustrate the connection. With this system one can achieve an extremely short interconnection length—as low as 0.010″ or less, having the ability to provide low loss interconnection at a bandwidth above 40 GHz.

Although this type of interconnection addresses the electrical needs, the small gap between the device and the board creates problems that need to be addressed. Specifically, many device packages place small components, such as capacitors, in the central area of the device, projecting downward. With a small gap between the device and board, the component will interfere with the board. Also, in handling the device during test and other operations, it is common practice to hold the device in a carrier 26 that has a lip that projects below package housing 20. This lip can also cause an interference between the device and board. The present invention addresses arrangements that eliminate these interferences.

### SUMMARY OF THE INVENTION

This invention features a high-performance separable electrical device/printed circuit board interconnection for an electrical device package having surface contacts on an active surface thereof, wherein the package is separably placed proximate to, and is electrically connected through its contacts to, an active surface of the printed circuit board, the package further comprising one or more projections extending from the active surface farther than the electrical device package surface contacts, the interconnection comprising a low-profile surface mount connector for accomplishing the electrical connection between the printed circuit board and the electrical device package, and a printed circuit board with an active surface having electrical connections thereon, wherein there are one or more recesses defined in the printed circuit board and/or in the surface mount connector, the recesses aligned with the projections extending from the active surface of the device package when the package is electrically connected to the printed circuit board, such that the projections fit into the recesses without touching the printed circuit board.

In one embodiment, there are one or more recesses in the active surface of the printed circuit board. In this case, the low-profile surface mount connector may comprise a layer of anisotropic conductive elastomer (ACE), and the ACE may define an opening aligned with a recess in the printed circuit board.

In another embodiment, the low-profile surface mount connector may comprise an extender board electrically connected to the printed circuit board by a first layer of anisotropic conductive elastomer (ACE). In this case, the recesses further comprise gaps in the extender board and aligned gaps in the first ACE layer that are vertically aligned with the gaps in the extender board, so that the recesses extend from the device package to the printed circuit board. The low-profile surface mount connector may then further comprise a second layer of ACE between the extender board and the device package, in which the recesses further comprise gaps in the second ACE layer that are vertically aligned with the gaps in the extender board, so that the recesses extend fully from the device package to the printed circuit board.

Also featured is a high-performance separable electrical device/printed circuit board interconnection, comprising a printed circuit board with an active surface having electrical connections thereon, an electrical device package having surface contacts on an active surface thereof, wherein the package is separably placed proximate to, and is electrically connected through its contacts to, the active surface of the printed circuit board, the package further comprising one or more projections extending from the active surface farther than the electrical device package surface contacts, and a layer of anisotropic conductive elastomer (ACE) for accomplishing the electrical connection between the printed circuit board and the electrical device package, wherein there are one or more recesses defined in the active surface of the printed circuit board, and wherein the ACE defines openings aligned with recesses in the printed circuit board, the recesses and the openings being aligned with the projections extending from the active surface of the device package when the package is electrically connected to the printed circuit board, such that the projections fit into the recesses without touching the printed circuit board.

Featured in yet another embodiment is a high-performance separable electrical device/printed circuit board interconnection, comprising a printed circuit board with an active surface having electrical connections thereon, an electrical device package having surface contacts on an active surface thereof, wherein the package is separably placed proximate to, and is electrically connected through its contacts to, the active surface of the printed circuit board, the package further comprising one or more projections extending from the active surface farther than the electrical device package surface contacts, and a low-profile surface mount connector for accomplishing the electrical connection between the printed circuit board and the electrical device package, wherein the low-profile surface mount connector comprises an extender board electrically connected to the printed circuit board by a first layer of anisotropic conductive elastomer (ACE), and a second layer of ACE between the extender board and the device package, wherein there are one or more gaps defined through the surface mount connector, the gaps aligned with the projections extending from the active surface of the device package when the package is electrically connected to the printed circuit board, such that the projections fit into the gaps without touching the printed circuit board.

### BRIEF DESCRIPTION OF THE DRAWINGS

Other objects, features and advantages will occur to those skilled in the art from the following description of the preferred embodiments and the accompanying drawings, in which:

FIGS. 1A and 1B are exploded and cross-sectional views, respectively, of a prior art spring probe electrical connector;

FIG. 2 is a cross-sectional, schematic view of a prior art high-speed separable electrical interconnect;

FIG. 3 is a cross-sectional, schematic view of one preferred embodiment of the invention; and

FIG. 4 is a cross-sectional, schematic view of an alternative preferred embodiment of the invention.

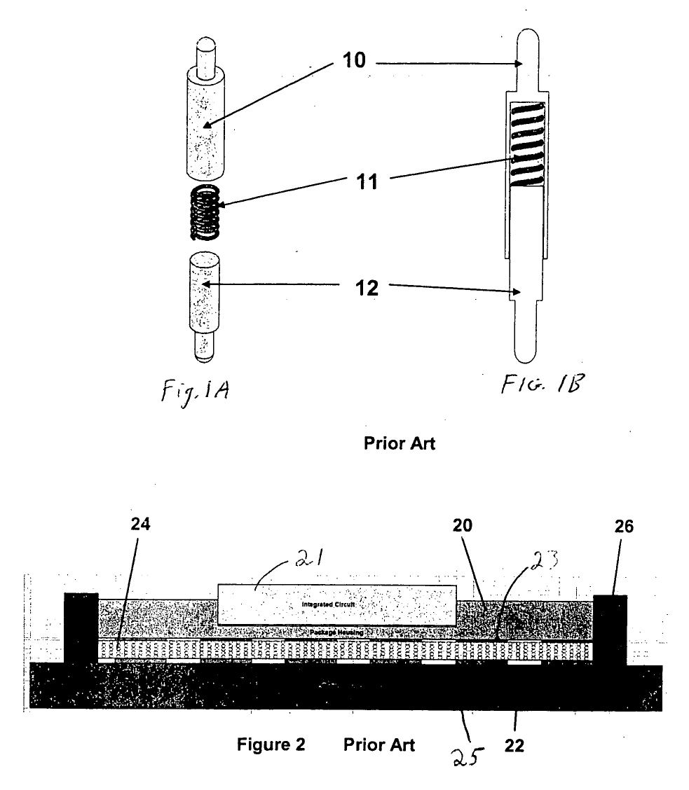

### DESCRIPTION OF THE PREFERRED EMBODIMENTS OF THE INVENTION

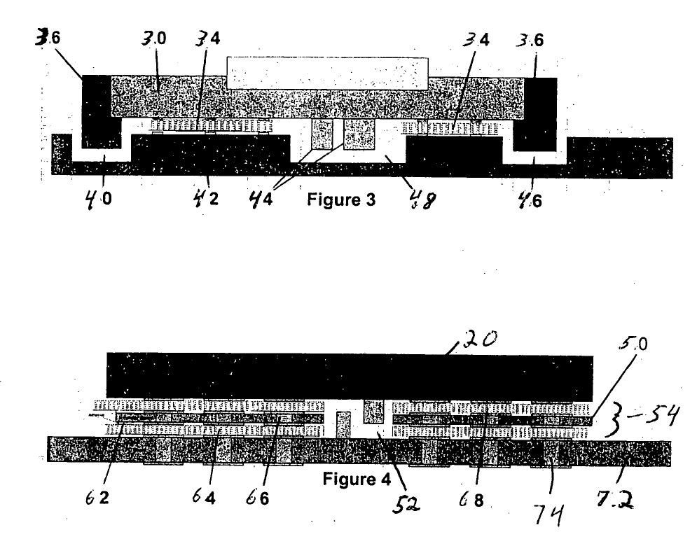

Printed circuit boards are essentially flat, continuous sheets of interconnection fabric. Conventional design provides for drilled mounting holes. FIG. 3 presents a cross sectional view of a printed circuit board 42 of this invention which has been modified to address the needs of a low profile connector. For this application, the board 42 has been modified by the introduction of recesses (for example, either formed or cut out areas) 40, 46 and 48 that accommodate the components 44 and holders 36 that protrude from the bottom of the device package 30. Areas 40, 48 and 46 would typically be made by routing out recesses of appropriate placement, size and depth to accommodate projections from the package, such that the projections do not hit the board. The board would be laid out electrically such that these recesses would not affect the functionality of the board. These recesses allow package 30 to sit close enough to board 42 so that ACE layer 34 can still be used to electrically connect the pad layer on the upper surface of board 42 with the pad layer on the bottom surface of device package 30.

In an alternative embodiment shown in FIG. 4, one or more recesses or gaps 52 in the low-profile connector are created by elevating device package 20 sufficiently to accommodate the components, using an intermediate adapter or extender board 50 to accomplish the elevation. Board 50 has plated through holes 66 that are properly aligned with the contacts on board 72 having plated-through holes 74, and also aligned with the contacts on device package 20. Electrical connection is provided with two layers of ACE material, an upper layer 68 that interconnects device package 20 and adapter 50, and a lower layer 64 that interconnects adapter 50 and board 72. This whole extender assembly 54 can be effectively made unitary by including an adhesive 62 that adheres ACE layers 64 and 68 to board 50. Gaps 52 are created with appropriate sized, shaped and located through openings in both layers of ACE and in the extender board, such that the gaps extend all the way between the device package and the main board, or as far therebetween as necessary in order to accommodate the components projecting from the device package. For example, the gaps could be located only in first ACE layer 68, or in that layer and extender board 50, or in all three components of connector 54.

Although specific features of the invention are shown in some drawings and not others, this is for convenience only, as the features may be combined with one another in accordance with the invention.

Other embodiments will occur to those skilled in the art and are within the following claims.

What is claimed is:

1. A high-performance separable electrical device/printed circuit board interconnection for an electrical device package having surface contacts on an active surface thereof, wherein the package is separably placed proximate to, and is electrically connected through its contacts to, an active surface of the printed circuit board, the package further comprising one or more projections extending from the active surface farther than the electrical device package surface contacts, the interconnection comprising:
a low-profile surface mount connector for accomplishing the electrical connection between the printed circuit board and the electrical device package; and
a printed circuit board with an active surface having electrical connections thereon, wherein there are one or more recesses defined in the printed circuit board and/or in the surface mount connector, the recesses aligned with the projections extending from the active surface of the device package when the package is electrically connected to the printed circuit board, such that the projections fit into the recesses without touching the printed circuit board.

2. The high-performance separable electrical device/printed circuit board interconnection of claim 1 wherein there are one or more recesses in the active surface of the printed circuit board.

3. The high-performance separable electrical device/printed circuit board interconnection of claim 2 wherein the low-profile surface mount connector comprises a layer of anisotropic conductive elastomer (ACE).

4. The high-performance separable electrical device/printed circuit board interconnection of claim 3 wherein the ACE defines an opening aligned with a recess in the printed circuit board.

5. The high-performance separable electrical device/printed circuit board interconnection of claim 1 wherein the low-profile surface mount connector comprises an extender board electrically connected to the printed circuit board by a first layer of anisotropic conductive elastomer (ACE).

6. The high-performance separable electrical device/printed circuit board interconnection of claim 5 wherein a recess further comprises a gap in the extender board.

7. The high-performance separable electrical device/printed circuit board interconnection of claim 6 wherein a recess further comprises a gap in the first ACE layer that is vertically aligned with the gap in the extender board, so that there is a recess from the device package to the printed circuit board.

8. The high-performance separable electrical device/printed circuit board interconnection of claim 7 wherein the low-profile surface mount connector further comprises a second layer of ACE between the extender board and the device package.

9. The high-performance separable electrical device/printed circuit board interconnection of claim 8 wherein a recess further comprises a gap in the second ACE layer that is vertically aligned with the gap in the extender board, so that there is a recess from the device package to the printed circuit board.

10. A high-performance separable electrical device/printed circuit board interconnection, comprising:
a printed circuit board with an active surface having electrical connections thereon;
an electrical device package having surface contacts on an active surface thereof, wherein the package is separably placed proximate to, and is electrically connected through its contacts to, the active surface of the printed circuit board, the package further comprising one or more projections extending from the active surface farther than the electrical device package surface contacts; and
a layer of anisotropic conductive elastomer (ACE) for accomplishing the electrical connection between the printed circuit board and the electrical device package;
wherein there are one or more recesses defined in the active surface of the printed circuit board, and wherein the ACE defines openings aligned with recesses in the printed circuit board, the recesses and the openings being aligned with the projections extending from the active surface of the device package when the package is electrically connected to the printed circuit board, such that the projections fit into the recesses without touching the printed circuit board.

11. A high-performance separable electrical device/printed circuit board interconnection, comprising:
a printed circuit board with an active surface having electrical connections thereon;
an electrical device package having surface contacts on an active surface thereof, wherein the package is separably placed proximate to, and is electrically connected through its contacts to, the active surface of the printed circuit board, the package further comprising one or more projections extending from the active surface farther than the electrical device package surface contacts; and
a low-profile surface mount connector for accomplishing the electrical connection between the printed circuit board and the electrical device package, wherein the low-profile surface mount connector comprises an extender board electrically connected to the printed circuit board by a first layer of anisotropic conductive elastomer (ACE), and a second layer of ACE between the extender board and the device package;
wherein there are one or more gaps defined through the surface mount connector, the gaps aligned with the projections extending from the active surface of the device package when the package is electrically connected to the printed circuit board, such that the projections fit into the gaps without touching the printed circuit board.
